(19) United States
(12) Patent Application Publication
(10) Pub. No.: US 2025/0079186 A1
(43) Pub. Date: Mar. 6, 2025

(54) Opaque Thermal Layer for Silicon Carbide Substrates

(71) Applicant: Applied Materials, Inc., Santa Clara, CA (US)

(72) Inventor: Yi ZHENG, Sunnyvale, CA (US)

(21) Appl. No.: 18/239,414

(22) Filed: Aug. 29, 2023

(51) Int. Cl. H01L 21/324; H01L 21/02; H01L 29/16

(52) U.S. Cl. CPC H01L 21/324; H01L 21/02115; H01L 21/02126; H01L 21/0214; H01L 21/02167; H01L 21/022; H10D 62/8325; H01L 21/0455; H01L 21/0485; H01L 21/31053

(57) ABSTRACT

A method for thermally processing an optically nonopaque substrate using radiant energy. In some embodiments, the method includes flipping the optically nonopaque substrate to expose a non-structure side, depositing an opaque thermal layer on the non-structure side of the optically nonopaque substrate where the opaque thermal layer has a uniform thickness, flipping the optically nonopaque substrate to expose the structure side, and thermally processing the optically nonopaque substrate in excess of approximately 900 degrees Celsius. In some embodiments, the opaque thermal layer is comprised of amorphous carbon, multiple layers of amorphous carbon with adjacent layers of the multiple layers having different optical properties, or alternating layers of different materials where a first layer of the alternating layers is comprised of amorphous carbon material and where a second layer of the alternating layers is comprised of amorphous silicon (Si)-based material.

### FIELD

Embodiments of the present principles generally relate to semiconductor processing of semiconductor substrates.

### BACKGROUND

Substrates are often heated during processing. The heating of the substrates is generally accomplished using lamps that radiate energy that is absorbed by the substrate causing the substrate temperature to increase. However, if the substrate material is transparent rather than opaque, the radiant energy is not absorbed by the substrate. Thus, for transparent substrates, lamps are not an efficient way to heat the substrate. Instead, the transparent substrates are heated using conductive heating using heated substrate supports, that is, susceptors. The inventor has observed, however, that the use of conductive heating surfaces causes uneven heating of the transparent substrates and particle generation.

Accordingly, the inventor has provided methods for heating an optically nonopaque substrate with improved thermal control.

### SUMMARY

Methods for improving temperature control of transparent substrates are provided herein.

In some embodiments, a method for processing an optically nonopaque substrate may comprise providing the optically nonopaque substrate with a structure side and a non-structure side and depositing an opaque thermal layer onto an entirety of a non-structure side of the optically nonopaque substrate and where the opaque thermal layer is approximately uniform in thickness and withstands thermal processing in excess of approximately 900 degrees Celsius.

In some embodiments, the method may further include an optically nonopaque substrate that is a silicon carbide substrate, processing the optically nonopaque substrate with the opaque thermal layer where the optically nonopaque substrate undergoes thermal processing in excess of approximately 1300 degrees Celsius and where structures are formed on the structure side of the optically nonopaque substrate and backgrinding the optically nonopaque substrate to remove the opaque thermal layer, at least one structure of the structures that includes a gate of a power transistor, a thermal processing that is approximately 1650 degrees Celsius or greater, an opaque thermal layer that is comprised of amorphous carbon, an opaque thermal layer that is comprised of multiple layers of amorphous carbon material and adjacent layers of the multiple layers that have different optical properties, an opaque thermal layer that is comprised of alternating layers of different materials, a first layer of the alternating layers that is tuned to absorb a first range of wavelengths and a second layer of the alternating layers underneath the first layer that is tuned to reflect the first range of wavelengths back into the first layer, a first layer of the alternating layers that is comprised of an amorphous carbon material and a second layer of the alternating layers that is comprised of an amorphous silicon (Si)-based material, an amorphous silicon (Si)-based material is amorphous SiHₓ, amorphous SiCₓH_{y}, amorphous SiCₓN_{y}H_{z}, amorphous SiOₓH_{y}, or amorphous SiCONH, a thermal processing that includes radiant energy from at least one lamp-based energy source, a thermal processing that is approximately 1850 degrees Celsius or greater, an opaque thermal layer that is comprised of multiple layers, each of the multiple layers is tuned to absorb different ranges of wavelengths, different ranges of wavelengths that overlap, an opaque thermal layer that is tuned to absorb a first range of wavelengths that is less than but within a second range of wavelengths emitted by an infrared emitter of a process chamber, and/or an opaque thermal layer that is tuned to absorb a range of wavelengths emitted by an infrared emitter of a process chamber.

In some embodiments, a non-transitory, computer readable medium having instructions stored thereon that, when executed, cause a method for thermally processing an optically nonopaque substrate to be performed, the method may comprise providing the optically nonopaque substrate with a structure side and a non-structure side and depositing an opaque thermal layer on an entirety of the non-structure side of the optically nonopaque substrate and where the opaque thermal layer is uniform in thickness and withstands temperatures to approximately 2000 degrees, and absorbs radiant energy from lamp-based energy sources.

In some embodiments, the method of the non-transitory, computer readable medium includes an opaque thermal layer that is comprised of amorphous carbon and/or an opaque thermal layer that is comprised of multiple layers of amorphous carbon material and adjacent layers of the multiple layers that have different optical properties or an opaque thermal layer that is comprised of alternating layers of different materials including a first layer of the alternating layers comprised of amorphous carbon material and a second layer of the alternating layers comprised of amorphous silicon (a-Si)-based material.

Other and further embodiments are disclosed below.

### BRIEF DESCRIPTION OF THE DRAWINGS

Embodiments of the present principles, briefly summarized above and discussed in greater detail below, can be understood by reference to the illustrative embodiments of the principles depicted in the appended drawings. However, the appended drawings illustrate only typical embodiments of the principles and are thus not to be considered limiting of scope, for the principles may admit to other equally effective embodiments.

FIG. 1 is a method for processing an optically nonopaque substrate in accordance with some embodiments of the present principles.

FIG. 2 depicts cross-sectional views of a processing the optically nonopaque substrate in accordance with some embodiments of the present principles.

FIG. 3 is a method of depositing an opaque thermal layer in accordance with some embodiments of the present principles.

FIG. 4 depicts a cross-sectional view of a depositing an opaque thermal layer onto an optically nonopaque substrate in accordance with some embodiments of the present principles.

FIG. 5 is a method of depositing an opaque thermal layer in accordance with some embodiments of the present principles.

FIG. 6 depicts a cross-sectional view of a depositing an opaque thermal layer onto an optically nonopaque substrate in accordance with some embodiments of the present principles.

FIG. 7 depicts a top-down view of an integrated tool in accordance with some embodiments of the present principles.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

The methods provide improved temperature control for thermal processing of optically nonopaque substrates. Control of temperature ramping, both increasing and decreasing, is substantially improved over conductive heating methods. By integrating an opaque thermal layer on the backside of a transparent substrate, the transparent substrate can be heated using radiant energy from lamps rather than conductive heating sources. The opaque thermal layer can be tuned based on composition and thickness to absorb light and, in particular, the infrared (IR) band which is the most efficient way to heat a substrate. In addition, the opaque thermal layer provides good mechanical and tribology properties that protects the transparent substrate when interacting with end effectors during movement of the transparent substrate. As such, the opaque thermal layer remains integrated with the transparent substrate during the entire processing flow of the transparent substrate until a final backgrinding step is completed which removes the opaque thermal layer.

Silicon carbide (SiC) materials are becoming more popular for power devices such as power transistors and the like. The SiC substrate is optically nonopaque and can vary from crystal clear (optically transparent) to a yellowish transparency (optically translucent), depending on dopant levels of the SiC substrate. In some embodiments, the SiC substrate is optically transparent. In some embodiments, the SiC substrate is optically translucent. In some embodiments, the SiC substrate may regions of the substrate that vary between optically transparent regions and optically translucent regions. SiC substrates require temperatures in excess of 1500 degrees Celsius to process which is substantially higher than typical silicon substrates. Many front-end processes including gate dielectric deposition, epitaxial growth, rapid thermal processing (RTP), and silicide formation are thermal processes that use lamps to heat up substrates. However, lamp radiant energy for heating is inefficient with SiC substrates due to the SiC substrates optical transparency. The high voltage MOSFET built on SiC substrates are also more vulnerable to scratching during handling by robotic arms and blades. The semiconductor industry traditionally uses susceptors as heat absorbers to heat up SiC substrates indirectly via conduction. However, conduction heating is inefficient and leads to temperature non-uniformity and particle generation issues, especially for higher temperatures beyond 1300 degrees Celsius.

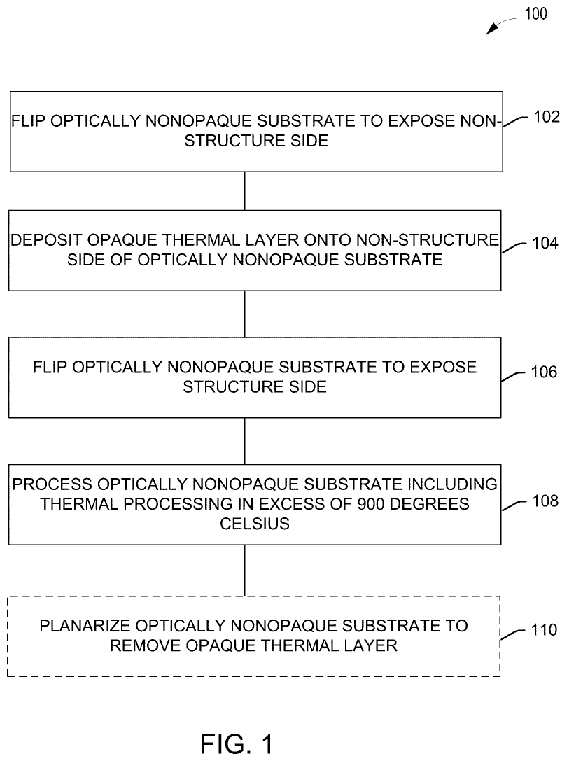

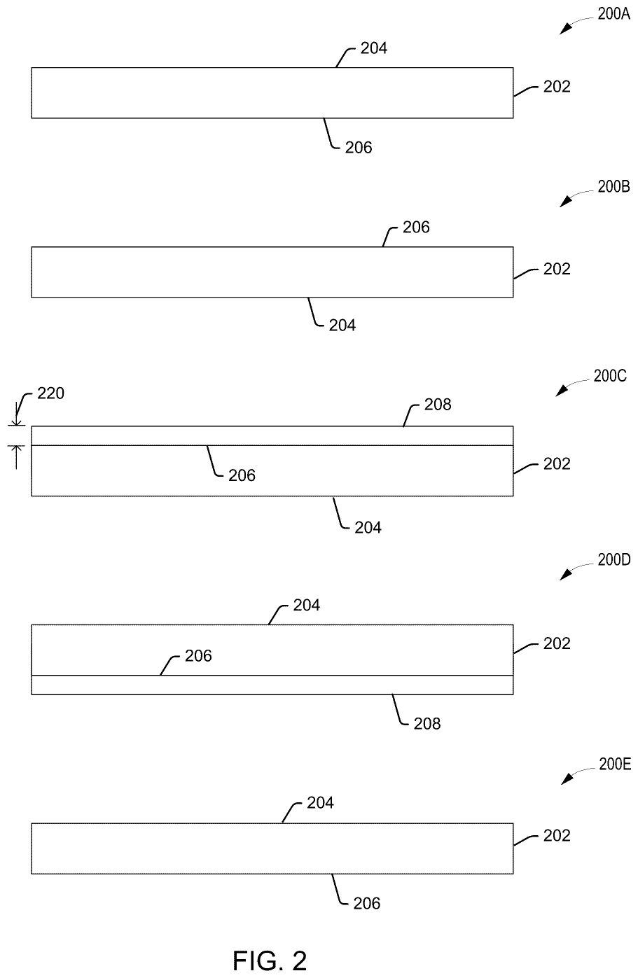

FIG. 1 is a method 100 of processing an optically nonopaque substrate 202 as depicted in a view 200A of FIG. 2. The optically nonopaque substrate 202 has a structure side 204 on which semiconductor structures are formed and a non-structure side 206 or backside of the optically nonopaque substrate 202 where structures are not formed (structureless side). The structures may include power transistor structures including gate dielectric materials and poly-Si or metal gate and the like. The gate structures may undergo high temperature doping/implanting and other processing in the formation of the transistor. In some embodiments, the optically nonopaque substrate 202 is formed of SiC material. In block 102, the optically nonopaque substrate 202 is flipped to expose the non-structure side 206 of the optically nonopaque substrate 202 as depicted in a view 200B of FIG. 2. In block 104, an opaque thermal layer 208 is deposited onto the non-structure side 206 of the optically nonopaque substrate 202 as depicted in a view 200C of FIG. 2. The opaque thermal layer 208 becomes an integral part of the optically nonopaque substrate 202 for the duration of the processing of the optically nonopaque substrate 202. In some embodiments, the opaque thermal layer 208 covers the entire non-structure side of the optically nonopaque substrate 202. In some embodiments, the opaque thermal layer 208 covers a substantial portion of the entire non-structure side 206 of the optically nonopaque substrate 202.

The opaque thermal layer 208 has an approximately uniform thickness 220 whether formed of a single layer or multiple layers (multiple discussed below). In some embodiments, the uniform thickness 220 has a thickness variability of approximately +/−10% or less. In some embodiments, the uniform thickness 220 has a thickness variability of approximately +/−5% or less. In some embodiments, the uniform thickness 220 has a thickness variability of approximately +/−2% or less. In some embodiments, the uniform thickness 220 has a thickness variability of approximately +/−1% or less. The opaque thermal layer 208 functions to provide thermal control of the optically nonopaque substrate 202 and also to protect the optically nonopaque substrate 202 from robotic arms and end effectors during transport. In some embodiments, the optically nonopaque substrate 202 has one or more materials deposited on the optically nonopaque substrate 202 in one or more deposition chambers using one or more chemical vapor deposition (CVD) processes or plasma enhanced CVD (PECVD) processes discussed below. The chemical composition of the deposition or depositions and/or the thickness of the deposition can be used to modify the optical properties of the opaque thermal layer 208 in order to further control the temperature of the optically nonopaque substrate 202 during subsequent processing.

In block 106, the optically nonopaque substrate 202 is flipped to expose the structure side 204 (e.g., diodes and/or MOSFET transistors, etc.) of the optically nonopaque substrate 202 as depicted in a view 200D of FIG. 2. In block 108, the optically nonopaque substrate 202 undergoes processing which includes thermal processing in excess of 900 degrees Celsius. For example, silicide formation of source contacts may reach temperatures of approximately 900 degrees Celsius to approximately 1100 degrees Celsius, dopant activation anneal may reach temperatures of approximately 1600 degrees Celsius to approximately 1800 degrees Celsius, and epitaxy processes may reach temperatures of approximately 1600 degrees Celsius to approximately 2000 degrees Celsius. In some embodiments, implantation or doping of the optically nonopaque substrate 202 is part of the processing and the optically nonopaque substrate 202 may be heated to temperatures of 1650 degrees Celsius or greater. In some embodiments, the temperature may be 1850 degrees Celsius or greater for shorter durations. In some embodiments, the temperatures may reach approximately 2000 degrees Celsius for very short durations. The benefit of short anneal duration at high temperature is higher dopant activation levels, reduction in growth of some crystalline defects, and achieving desired dopant profiles. The high annealing temperatures, for example, are needed to activate dopants into materials like SiC of a SiC substrate. The processing may include other processes such as structure formation, etching, and/or depositions and the like to complete a finished optically nonopaque substrate. In block 110, the optically nonopaque substrate undergoes a planarization process such as, for example but not limited to, a backgrinding process to remove the integrated opaque thermal layer as depicted in a view 200E of FIG. 2. The opaque thermal layer 208 is integrated as part of the substrate as the layer functions as both a thermal controller as well as a protector of the substrate to minimize particle formation and damage to the backside of the substrate during processing of the substrate. When processing of the substrate is completed, the opaque thermal layer 208 may be left in place or removed, for example, to expose backside contacts and the like.

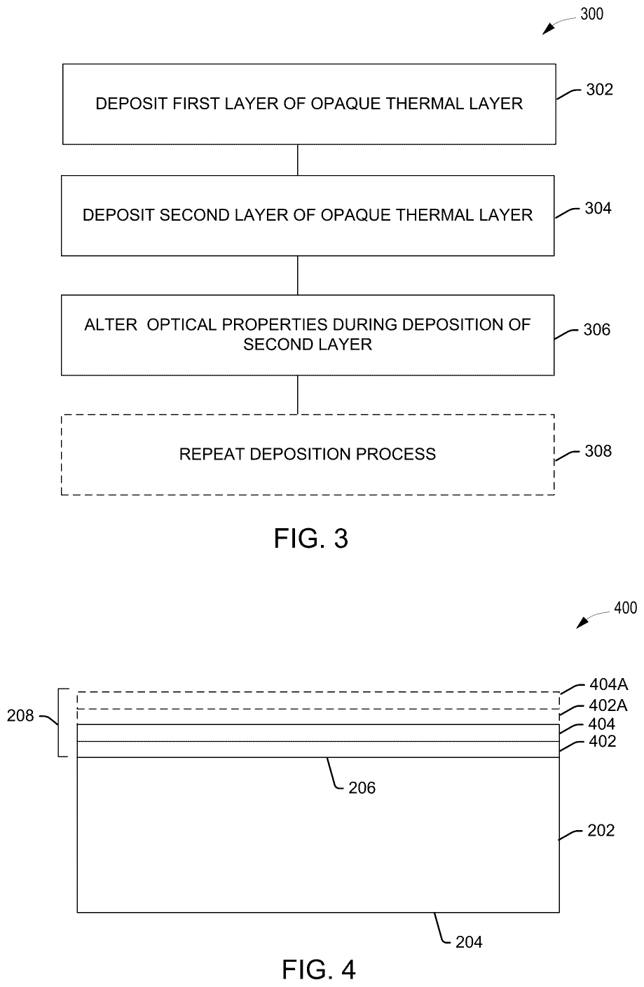

FIG. 3 is a method 300 of depositing the opaque thermal layer 208 onto the optically nonopaque substrate 202 after the substrate has been flipped (i.e., a first method for block 104). The opaque thermal layer 208 may be formed as a single layer of a single composition having a single set of optical properties which influence the control of the temperature across the optically nonopaque substrate 202 as depicted in views 200C and 200D of FIG. 2. In such a case, the opaque thermal layer 208 absorbs radiated energy from lamp sources within a heating chamber according to the thickness and composition of the material which makes up the opaque thermal layer 208. In method 300, a single material is used but with different optical properties in different layers. In block 302, a first layer 402 of the opaque thermal layer 208 is deposited on the optically nonopaque substrate 202 as depicted in a view 400 of FIG. 4. In some embodiments, the first layer 402 may be an a-C layer with a first set of optical properties.

In block 304, a second layer 404 of the opaque thermal layer 208 is deposited on the optically nonopaque substrate 202 as depicted in a view 400 of FIG. 4. In block 306, the optical properties of the second layer 404 are altered during deposition of the second layer 404. The optical properties include, but are not limited to, the refractive index (RI) or n value of the layer and the extinction coefficient or k value of the layer. Optical properties can be altered during deposition by changing precursor amounts or types during the deposition of a similar material such as, but not limited to, a-C or amorphous SiCₓH_{y} and the like. For example, a-C:H film optical properties (n and k values can be tuned by varying the hydrogen content and carbon-to-carbon bonding configuration (sp2 or sp3) and the like. In some embodiments, the second layer 404 may be an a-C layer with a second set of optical properties that are different from the first set of optical properties. In block 308, the deposition process may be repeated (e.g., layers 402A, 404A, etc.) any number of times until a desired overall thermal control is achieved through thickness variations of the layers and/or through optical property variations of the layers. In some embodiments, in order to provide protection for the optically nonopaque substrate 202, the topmost layer, when the substrate is flipped, is a material that provides a smooth, hard surface such as, but not limited to, a-C or amorphous SiCₓH_{y} and the like.

The different optical properties of each layer cause incident infrared waves of different frequencies to be absorbed in each of the layers which produces heat that is conducted through the layers to the optically nonopaque substrate 202 to allow for multiple wavelength heating of the substrate. Whereas, with a single layer opaque thermal layer, the optical properties of the opaque thermal layer would absorb a smaller range of infrared wavelengths which would cause a smaller amount of heat to be conducted back into the optically nonopaque substrate, causing a reduction in the thermal heating performance of the opaque thermal layer. Another advantage of using a single material but with different optical properties in a multiple layer format is that a single chamber can be used to deposit the multiple layers while still increasing the thermal performance and wavelength range of the opaque thermal layer. In some embodiments, the optical properties of the first layer 402 can be adjusted to absorb a first range of infrared wavelengths. The optical properties of the second layer 404 can be adjusted to reflect the first range of infrared wavelengths back into the first layer 402. The reflection of the first range of infrared wavelengths back into the first layer 402 by the second layer 404 increases the absorption efficiency of the first layer 402 and subsequently the conductive heating efficiency of the optically nonopaque substrate 202, In some embodiments, the optical properties of the first layer 402 can be adjusted to absorb a first range of infrared wavelengths and the optical properties of the second layer 404 can be adjusted to absorb a second range of infrared wavelengths. The absorption of the first range of infrared wavelengths combined with the absorption of the second range of infrared wavelengths can allow the opaque thermal layer 208 to provide heat conduction to the optically nonopaque substrate 202, for example, in multiple chambers (multiple processing steps, etc.) that operate with different infrared frequencies without requiring changes to the opaque thermal layer 208, saving time and costs.

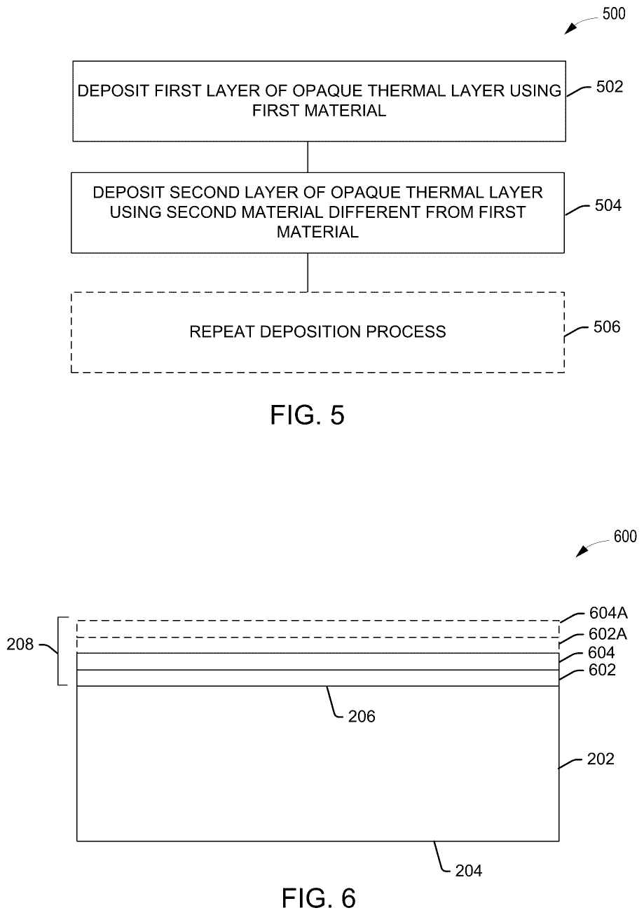

FIG. 5 is a method 500 of depositing the opaque thermal layer 208 onto the optically nonopaque substrate 202 after the substrate has been flipped (i.e., a first method for block 104). In method 500, more than one material is used in alternating layers, each with different optical properties. In block 502, a first layer 602 of the opaque thermal layer 208 is deposited on the optically nonopaque substrate 202 as depicted in a view 600 of FIG. 6. In some embodiments, the first layer 602 may be an a-C layer with a first set of optical properties. In block 504, a second layer 604 of the opaque thermal layer 208 is deposited on the optically nonopaque substrate 202 as depicted in a view 600 of FIG. 6. In some embodiments, the second layer 604 may be, but is not limited to, an amorphous silicon-based material such as amorphous SiHₓ, amorphous SiCₓH_{y}, amorphous SiCₓN_{y}H_{z}, amorphous SiOₓH_{y}, amorphous SiCONH, or the like.

During the deposition of the first layer 602 or the second layer 604, the optical properties of the layer may be further altered over just the optical properties of the material alone to further provide thermal control of the optically nonopaque substrate 202. The optical properties include, but are not limited to, the refractive index (n) or extinction coefficient (k) value of the layer. Optical properties can be altered during deposition by changing precursor amounts or types during the deposition. In block 506, the deposition process may be repeated (e.g., layers 602A, 604A, etc.) any number of times until a desired overall thermal control is achieved through thickness variations of the layers and/or through optical property variations of the layers. In some embodiments, each layer of a similar material may have different thicknesses or the same thicknesses. In some embodiments, in order to provide protection for the optically nonopaque substrate 202, the topmost layer, when the substrate is flipped, is a material that provides a smooth, hard surface such as, but not limited to, a-C and the like. The different optical properties of each layer cause incident infrared waves of different frequencies to be absorbed in each of the layers to conduct heat back through to the optically nonopaque substrate 202 to allow for multiple wavelength heating of the substrate.

In some embodiments, the optical properties of the first layer 602 can be adjusted to absorb a first range of infrared wavelengths. The optical properties of the second layer 604 can be adjusted to reflect the first range of infrared wavelengths back into the first layer 602. The reflection of the first range of infrared wavelengths back into the first layer 602 by the second layer 604 increases the absorption efficiency of the first layer 602 and subsequently the conductive heating efficiency of the optically nonopaque substrate 202, In some embodiments, the optical properties of the first layer 602 can be adjusted to absorb a first range of infrared wavelengths and the optical properties of the second layer 604 can be adjusted to absorb a second range of infrared wavelengths. The absorption of the first range of infrared wavelengths combined with the absorption of the second range of infrared wavelengths can allow the opaque thermal layer 208 to provide heat conduction to the optically nonopaque substrate 202, for example, in multiple chambers (multiple processing steps, etc.) that operate with different infrared frequencies without requiring changes to the opaque thermal layer 208, saving time and costs.

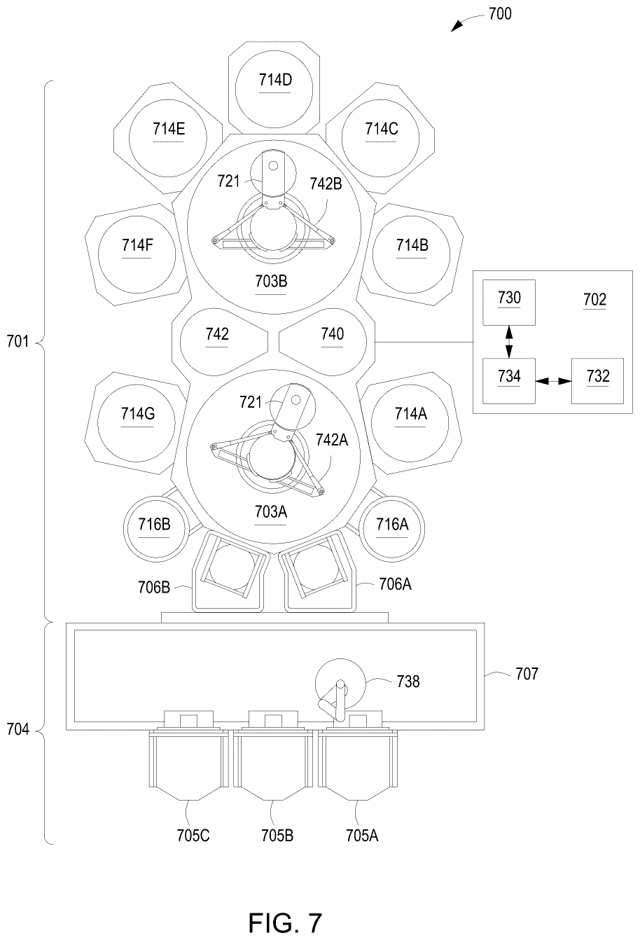

The use of different materials in multiple layers of an opaque thermal layer has the advantage of affording a greater degree of tuning over multiple layers using a single material with different optical properties. For example, a-C:H material may have a refractive index of approximately 1.6 to approximately 1.94 and a coefficient of extinction of approximately 0.03 to approximately 0.65. a-Si:H material may have a refractive index of approximately 3.3 to approximately 4.5 and a coefficient of extinction of approximately 0.019 to approximately 0.24. SiₓN_{y}H_{z} material may have a refractive index of approximately 1.95 to approximately 2.4. SiCₓH_{y} material may have a refractive index of approximately 2.1 to approximately 2.6 and a coefficient of extinction of approximately zero. SiCₓN_{y}H_{z} material may have a refractive index of approximately 2.0 to approximately 2.2. By altering the material of a layer and the optical properties of the material, an opaque thermal layer with multiple layers of multiple materials will have a substantial advantage in tuning flexibility to control thermal properties of the optically nonopaque substrate over an opaque thermal layer with multiple layers of a single material or a single layer opaque thermal layer. Although different chambers may be utilized to deposit the multiple layers of different materials, the deposition process may be achieved using a single integrated tool such as, but not limited to, the integrated tool depicted in FIG. 7. The tunability of the present principles allows for easy alteration of the opaque thermal layer on a substrate by substrate or chamber by chamber basis based on substrate and/or chamber infrared heating wavelengths and the like.

The opaque thermal layer 208 is tunable using the above methods to achieve overall optical properties that allow precise temperature responses for the optically nonopaque substrate 202. When the optically nonopaque substrate 202 is placed in a heating chamber that uses radiant energy as a heating source, the radiant energy passes through the optically nonopaque substrate 202 with negligible change in temperature of the substrate. The opaque thermal layer 208, when integrated onto the optically nonopaque substrate 202, intercepts radiant energy passing through the optically nonopaque substrate 202 and allows predictable control of how the radiant energy from the lamps is converted into heat energy that flows back into the optically nonopaque substrate 202. The opaque thermal layer 208 enables quick and precise responses to changes in the radiant energy and transfer into the optically nonopaque substrate that is not achievable using conductive type heaters such as heated susceptors and the like. In some embodiments, the opaque thermal layer 208 can have optical properties that are tuned to the IR frequency range of the lamps used in a rapid temperature process (RTP) chamber to increase the heating efficiency and temperature change control speed (response times) of the optically nonopaque substrate 202.

The methods described herein may be performed in an individual process chamber or may be performed in a cluster tool such as, for example, an integrated tool 700 described below with respect to FIG. 7. The advantage of using an integrated tool 700 is that there is no vacuum break and no substantial process lag between depositions. The integrated tool 700 includes a vacuum-tight processing platform 701, a factory interface 704, and a system controller 702. The processing platform 701 comprises multiple processing chambers, such as 714A, 714B, 714C, 714D, 714E, 714F, and 714G operatively coupled to a vacuum substrate transfer chamber (transfer chambers 703A, 703B). The factory interface 704 is operatively coupled to the transfer chamber 703A by one or more load lock chambers (two load lock chambers, such as 706A and 706B shown in FIG. 7).

In some embodiments, the factory interface 704 comprises at least one docking station 707, at least one factory interface robot 738 to facilitate the transfer of the semiconductor substrates. The docking station 707 is configured to accept one or more front opening unified pod (FOUP). Three FOUPS, such as 705A, 705B, and 705C are shown in the embodiment of FIG. 7. The factory interface robot 738 is configured to transfer the substrates from the factory interface 704 to the processing platform 701 through the load lock chambers, such as 706A and 706B. Each of the load lock chambers 706A and 706B have a first port coupled to the factory interface 704 and a second port coupled to the transfer chamber 703A. The load lock chamber 706A and 706B are coupled to a pressure control system (not shown) which pumps down and vents the load lock chambers 706A and 706B to facilitate passing the substrates between the vacuum environment of the transfer chamber 703A and the substantially ambient (e.g., atmospheric) environment of the factory interface 704. The transfer chambers 703A, 703B have vacuum robots 742A, 742B disposed in the respective transfer chambers 703A, 703B. The vacuum robot 742A is capable of transferring substrates 721 between the load lock chamber 706A, 706B, the processing chambers 714A and 714G and a cooldown station 740 or a pre-clean station 742. The vacuum robot 742B is capable of transferring substrates 721 between the cooldown station 740 or pre-clean station 742 and the processing chambers 714B, 714C, 714D, 714E, and 714F.

In some embodiments, the processing chambers 714A, 714B, 714C, 714D, 714E, 714F, and 714G are coupled to the transfer chambers 703A, 703B. The processing chambers 714A, 714B, 714C, 714D, 714E, 714F, and 714G may comprise a pre-clean chamber, a CVD chamber, a PECVD chamber, an ALD chamber, a rapid temperature process (RTP) chamber, and/or a PVD chamber. The process chambers may include any chambers suitable to perform all or portions of the methods described herein, as discussed above. In some embodiments, one or more optional service chambers (shown as 716A and 716B) may be coupled to the transfer chamber 703A. The service chambers 716A and 716B may be configured to perform other substrate processes, such as degassing, orientation, substrate metrology, cool down, and the like.

The system controller 702 controls the operation of the tool 700 using a direct control of the process chambers 714A, 714B, 714C, 714D, 714E, 714F, and 714G or alternatively, by controlling the computers (or controllers) associated with the process chambers 714A, 714B, 714C, 714D, 714E, 714F, and 714G and the tool 700. In operation, the system controller 702 enables data collection and feedback from the respective chambers and systems to optimize performance of the tool 700. The system controller 702 generally includes a Central Processing Unit (CPU) 730, a memory 734, and a support circuit 732. The CPU 730 may be any form of a general purpose computer processor that can be used in an industrial setting. The support circuit 732 is conventionally coupled to the CPU 730 and may comprise a cache, clock circuits, input/output subsystems, power supplies, and the like. Software routines, such as a method as described above may be stored in the memory 734 and, when executed by the CPU 730, transform the CPU 730 into a specific purpose computer (system controller 702). The software routines may also be stored and/or executed by a second controller (not shown) that is located remotely from the tool 700.

The memory 734 is in the form of computer-readable storage media that contains instructions, when executed by the CPU 730, to facilitate the operation of the semiconductor processes and equipment. The instructions in the memory 734 are in the form of a program product such as a program that implements the method of the present principles. The program code may conform to any one of a number of different programming languages. In one example, the disclosure may be implemented as a program product stored on a computer-readable storage media for use with a computer system. The program(s) of the program product define functions of the aspects (including the methods described herein). Illustrative computer-readable storage media include, but are not limited to: non-writable storage media (e.g., read-only memory devices within a computer such as CD-ROM disks readable by a CD-ROM drive, flash memory, ROM chips, or any type of solid-state non-volatile semiconductor memory) on which information is permanently stored; and writable storage media (e.g., floppy disks within a diskette drive or hard-disk drive or any type of solid-state random access semiconductor memory) on which alterable information is stored. Such computer-readable storage media, when carrying computer-readable instructions that direct the functions of the methods described herein, are aspects of the present principles.

Embodiments in accordance with the present principles may be implemented in hardware, firmware, software, or any combination thereof. Embodiments may also be implemented as instructions stored using one or more computer readable media, which may be read and executed by one or more processors. A computer readable medium may include any mechanism for storing or transmitting information in a form readable by a machine (e.g., a computing platform or a “virtual machine” running on one or more computing platforms). For example, a computer readable medium may include any suitable form of volatile or non-volatile memory. In some embodiments, the computer readable media may include a non-transitory computer readable medium.

While the foregoing is directed to embodiments of the present principles, other and further embodiments of the principles may be devised without departing from the basic scope thereof.

1. A method for processing an optically nonopaque substrate, comprising:
providing the optically nonopaque substrate with a structure side and a non-structure side; and
depositing an opaque thermal layer onto an entirety of the non-structure side of the optically nonopaque substrate, wherein the opaque thermal layer is approximately uniform in thickness and withstands thermal processing in excess of approximately 900 degrees Celsius.

2. The method of claim 1, wherein the optically nonopaque substrate is a silicon carbide substrate.

3. The method of claim 1, further comprising:
processing the optically nonopaque substrate with the opaque thermal layer, wherein the optically nonopaque substrate undergoes thermal processing in excess of approximately 1300 degrees Celsius and wherein structures are formed on the structure side of the optically nonopaque substrate; and
backgrinding the optically nonopaque substrate to remove the opaque thermal layer.

4. The method of claim 3, wherein at least one structure of the structures includes a gate of a power transistor.

5. The method of claim 1, wherein the thermal processing is approximately 1650 degrees Celsius or greater.

6. The method of claim 1, wherein the opaque thermal layer is comprised of amorphous carbon.

7. The method of claim 1, wherein the opaque thermal layer is comprised of multiple layers of amorphous carbon material and wherein adjacent layers of the multiple layers have different optical properties.

8. The method of claim 1, wherein the opaque thermal layer is comprised of alternating layers of different materials.

9. The method of claim 8, wherein a first layer of the alternating layers is tuned to absorb a first range of wavelengths and wherein a second layer of the alternating layers underneath the first layer is tuned to reflect the first range of wavelengths back into the first layer.

10. The method of claim 8, wherein a first layer of the alternating layers is comprised of an amorphous carbon material and wherein a second layer of the alternating layers is comprised of an amorphous silicon (Si)-based material.

11. The method of claim 10, wherein the amorphous silicon (Si)-based material is amorphous SiHₓ, amorphous SiCₓH_{y}, amorphous SiCₓN_{y}H_{z}, amorphous SiOₓH_{y}, or amorphous SiCONH.

12. The method of claim 1, wherein the thermal processing includes radiant energy from at least one lamp-based energy source.

13. The method of claim 1, wherein the thermal processing is approximately 1850 degrees Celsius or greater.

14. The method of claim 1, wherein the opaque thermal layer is comprised of multiple layers, each of the multiple layers is tuned to absorb different ranges of wavelengths.

15. The method of claim 14, wherein the different ranges of wavelengths overlap.

16. The method of claim 1, wherein the opaque thermal layer is tuned to absorb a first range of wavelengths that is less than but within a second range of wavelengths emitted by an infrared emitter of a process chamber.

17. The method of claim 1, wherein the opaque thermal layer is tuned to absorb a range of wavelengths emitted by an infrared emitter of a process chamber.

18. A non-transitory, computer readable medium having instructions stored thereon that, when executed, cause a method for thermally processing an optically nonopaque substrate to be performed, the method comprising:
providing the optically nonopaque substrate with a structure side and a non-structure side; and
depositing an opaque thermal layer on an entirety of the non-structure side of the optically nonopaque substrate, wherein the opaque thermal layer is approximately uniform in thickness, withstands temperatures to approximately 2000 degrees, and absorbs radiant energy from lamp-based energy sources.

19. The non-transitory, computer readable medium of claim 18, wherein the opaque thermal layer is comprised of amorphous carbon.

20. The non-transitory, computer readable medium of claim 18, wherein the opaque thermal layer is comprised of multiple layers of amorphous carbon material and wherein adjacent layers of the multiple layers have different optical properties or wherein the opaque thermal layer is comprised of alternating layers of different materials including a first layer of the alternating layers comprised of amorphous carbon material and a second layer of the alternating layers comprised of amorphous silicon (a-Si)-based material.
